(19) United States
(12) Patent Application Publication
(10) Pub. No.: US 2026/0182397 A1
(43) Pub. Date: Jun. 25, 2026

(54) EMBEDDED SEMICONDUCTOR DEVICE PACKAGES AND METHODS OF MANUFACTURE

(71) Applicant: SEMICONDUCTOR COMPONENTS INDUSTRIES, LLC, Scottsdale, AZ (US)

(72) Inventor: Ankit Bhushan SHARMA, Erding (DE)

(73) Assignee: SEMICONDUCTOR COMPONENTS INDUSTRIES, LLC, Scottsdale, AZ (US)

(21) Appl. No.: 18/989,162

(22) Filed: Dec. 20, 2024

(51) Int. Cl. H01L 23/495; H01L 21/48; H01L 21/56; H01L 23/31; H01L 23/373

(52) U.S. Cl. CPC H10W 70/461; H10W 40/037; H10W 40/255; H10W 74/01; H10W 74/121

(57) ABSTRACT

In a general aspect, a semiconductor device package includes a substrate including a non-conductive material, and a heat spreader disposed in the non-conductive material. A first surface of the heat spreader is exposed through a first side of the non-conductive material. The package further includes a semiconductor die disposed in a cavity defined in a second side of the non-conductive material opposite the first side. The semiconductor die is electrically coupled with the heat spreader in a recess defined in a second surface of the heat spreader opposite the first surface. The recess corresponds with the cavity in the non-conductive material. The package also includes a patterned metal layer that is electrically coupled with at least one of the semiconductor die or the heat spreader.

### SUMMARY

In a general aspect, a method for producing a semiconductor device package includes forming a panel including a heat spreader that is disposed in a non-conductive material. A first surface of the heat spreader is exposed through a first side of the non-conductive material and a second surface of the heat spreader opposite the first surface is embedded in the non-conductive material. The method further includes forming, on a second side of the non-conductive material opposite the first side, a cavity in the non-conductive material to expose the second surface of the heat spreader. Forming the cavity includes forming a recess in the second surface of the heat spreader. The method also includes coupling a semiconductor die to the second surface of the heat spreader with a conductive bonding material. The semiconductor die is disposed in the cavity. The method further includes embedding the semiconductor die in a lamination material, disposing a metal layer on the lamination material, and forming an opening in the metal layer and the lamination material to expose at least a portion of a contact pad of the semiconductor die, The method also includes forming a conductive via in the opening in the metal layer and the lamination material. The conductive via electrically couples the metal layer with the contact pad.

In another general aspect, a method for producing a semiconductor device package includes forming a panel including a heat spreader that is disposed in a non-conductive material. A first surface of the heat spreader is exposed through a first side of the non-conductive material, and a second surface of the heat spreader opposite the first surface is embedded in the non-conductive material. The method further includes forming, on a second side of the non-conductive material opposite the first side, a cavity in the non-conductive material to expose the second surface of the heat spreader. Forming the cavity includes forming a recess in the second surface of the heat spreader. The method also includes coupling a semiconductor die to the heat spreader with a conductive bonding material. The semiconductor die is disposed in the cavity. The method further includes applying an underfill material between a sidewall of the cavity and a sidewall of the semiconductor die. The method also includes forming, on the second side of the non-conductive material, a metal layer disposed on the non-conductive material, the underfill material and the semiconductor die. The method also includes patterning the metal layer to define at least one terminal of the semiconductor die.

In another general aspect, a semiconductor device package includes a substrate including a non-conductive material, and a heat spreader disposed in the non-conductive material. A first surface of the heat spreader is exposed through a first side of the non-conductive material. The package further includes a semiconductor die disposed in a cavity defined in a second side of the non-conductive material opposite the first side. The semiconductor die is electrically coupled with the heat spreader in a recess defined in a second surface of the heat spreader opposite the first surface. The recess corresponds with the cavity in the non-conductive material. The package also includes a patterned metal layer. The patterned metal layer is electrically coupled with at least one of the semiconductor die or the heat spreader.

### BRIEF DESCRIPTION OF THE DRAWINGS

FIG. 1A is a diagram schematically illustrating a cross-sectional view of an example semiconductor device package.

FIG. 1B is a diagram schematically illustrating a cross-sectional view of another example semiconductor device package.

FIG. 1C is a diagram schematically illustrating a cross-sectional view of another example semiconductor device package.

FIG. 2A is a diagram schematically illustrating a top view of a semiconductor device package, such as the semiconductor device packages of FIGS. 1A and/or 1B.

FIG. 2B is a diagram schematically illustrating a top view of another semiconductor device package, such as the semiconductor device package of FIG. 1C.

FIG. 2C is a diagram schematically illustrating a top view of another semiconductor device package.

FIGS. 3A to 3G are diagrams schematically illustrating an example process for producing a semiconductor device package, such as the semiconductor device packages of FIGS. 1A, 1B, 2A and/or 2C.

FIGS. 4A to 4D are diagrams schematically illustrating an example process for producing a semiconductor device package, such as the semiconductor device packages of FIGS. 1C and/or 2B.

FIG. 5 is flowchart illustrating a method that can be used to implement the process of FIGS. 3A to 3H.

FIG. 6 is a flowchart illustrating a method that can be used to implement the process of FIGS. 4A to 4D.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are by way of example, for purposes of illustrating example implementations and may not necessarily be to scale.

### DETAILED DESCRIPTION

This disclosure relates to packaged semiconductor devices that can be produced using printed circuit board (PCB) fabrication and/or embedding technologies. Such packaged semiconductor devices can be referred to as packages, semiconductor device packages, modules, assemblies, semiconductor device modules, power semiconductor device modules, semiconductor device assemblies, electronic device assemblies, etc. This disclosure further relates to associated methods for producing such semiconductor device packages using PCB fabrication and/or embedding techniques.

One technical problem with prior semiconductor device package implementations is under or over drilling (e.g., using laser ablation) of openings for forming conductive vias (e.g., via openings) due to thickness tolerance variations of heat spreaders included in a semiconductor device package (e.g., direct-bonded metal (DBM) substrates, active-metal brazing (AMB) substrates, metal (copper) plates or coins, etc.). For instance, in some implementations, DBM substrates and/or AMB substrates, such as insulating layers of such substrates, can have thickness tolerance variations on the order of +/−50 micrometers (μm). Metal plates or coins (such as conductive die attach paddles) can have thickness tolerance variations on the order of +/−30 μm. In some implementations, metallization (e.g., copper metallization) on a semiconductor die can have a thickness on the order of 10 μm. Accordingly, such thickness variations of a corresponding heat spreader can cause a via opening of a given depth to be insufficient to expose metallization (e.g., under drilling), or can result in removal of the metallization on the semiconductor die (e.g., over drilling).

Another technical problem with prior approaches is tilting of a semiconductor die and its associated heat spreader (e.g., substrate or metal plate) relative to lamination material used to embed the semiconductor die after attachment of the semiconductor die to the heat spreader. Such tilting can also result in over and/or under drilling of via openings. Yet another technical problem with prior approaches is mis-alignment (e.g., height differences) between a semiconductor die and corresponding lamination materials (e.g., prepreg materials, etc.) used for embedding the semiconductor die. Such mis-alignment can result in excessive pressure being applied to the semiconductor die during a vacuum lamination process, which can cause cracking and/or fracturing of the semiconductor die.

One technical solution that can address one or more of the foregoing technical problems is to couple a semiconductor die with a heat spreader in a cavity formed in non-conductive material (e.g., printed circuit board material) of a panel in which the heat spreader is included or embedded. In some implementations, forming the cavity includes forming a recess in the heat spreader (e.g., in a metal layer of a substrate or a metal plate). A depth of the cavity (including a recess in the heat spreader) can be referenced to a surface of the panel (e.g., to a surface of the non-conductive material of the panel), where the cavity depth corresponds with a thickness of the associated semiconductor die. A technical benefit of this technical solution is that it can account for thickness tolerance variations in a heat spreader and, as result, prevent or reduce the risk of over or under drilling of via openings. Another technical benefit of this technical solution is that it can prevent tilt of a semiconductor die relative to lamination materials used to embed the semiconductor die, as embedding of the semiconductor die can be performed after its attachment to the heat spreader. Still another technical benefit of the foregoing technical solution is that it can prevent or reduce mis-alignment (height differences) between a semiconductor die and associated lamination materials in prior approaches, which can, in turn, prevent or reduce cracking and/or fracturing of the semiconductor die during a lamination process used to embed the semiconductor die.

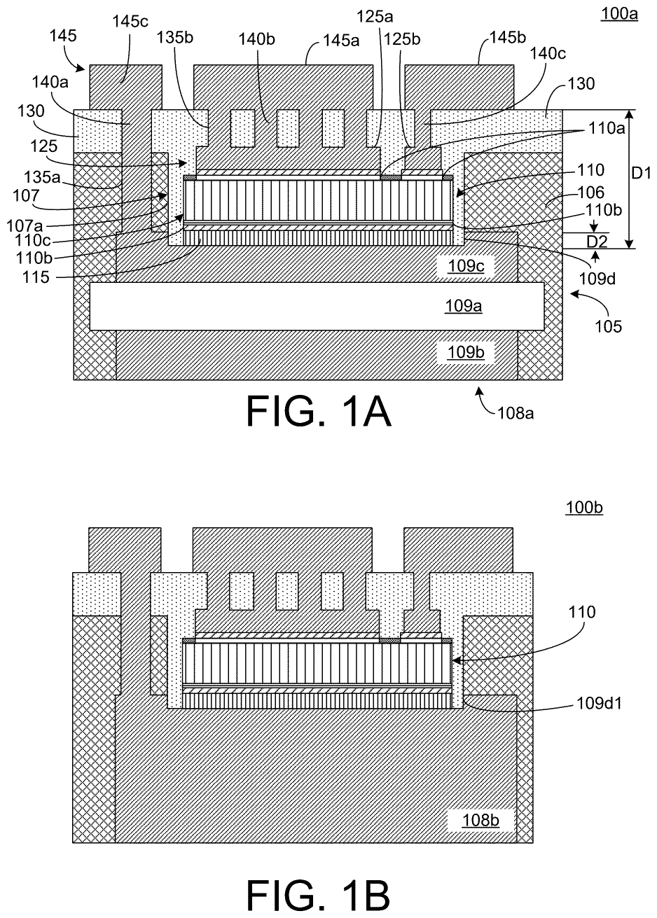

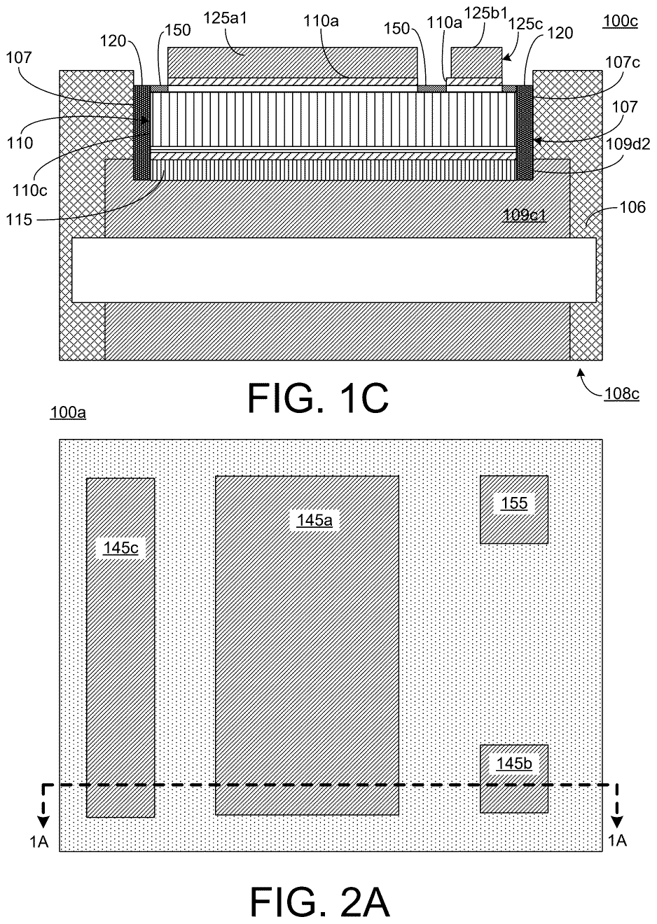

FIG. 1A is a diagram schematically illustrating a cross-sectional view of an example semiconductor device package 100a. As shown in FIG. 1A, the semiconductor device package 100a includes a substrate 105. The substrate 105 can be referred to as a panel, a portion of a panel, etc. In this example, the substrate 105 includes a non-conductive material 106, which can, e.g., be an elastomeric material, an organic material, a phenolic material, or a PCB/FR-4 material. The substrate 105 further includes a heat spreader, which, in this example, is a DBM substrate 108a (or could be an AMB substrate in some implementations.). In the example of FIG. 1A, the DBM substrate 108a includes an insulating layer 109a that is disposed between a first metal layer 109b and a second metal layer 109c. The insulating layer 109a can be, for example, a ceramic layer. In some implementations, the insulating layer can be, or can include, for example, a ceramic material such as alumina (Al₂O₃), aluminum nitride (AlN)), or silicon nitride (Si₃N₄)

In some implementations, the DBM substrate 108a can be formed by bonding one or more of the metal layers (e.g., the first metal layer 109b, the second metal layer 109c) to the insulating layer 109a. In some implementations, one or more of the metal layers 109b and/or 109c can be bonded to the insulating layer 109a using, for example, a high-temperature process and/or a lamination process.

In some implementations, the first metal layer 109b and/or the second metal layer 109c, as well as the insulating layer 109a, can function as a heat spreader and/or a heat sink. In some implementations, the first metal layer 109b (e.g., a surface of the first metal layer 109b exposed through the non-conductive material 106) can be coupled to a heat sink or other heat dissipation component. In some implementations, at least a portion of one or more of a first metal layer or a second metal layer of an DBM substrate or and AMB substrate can be exposed through a molding material or other non-conductive material, such as the non-conductive material 106 shown in FIG. 1A.

In some implementations, the first metal layer 109b and/or the second metal layer 109c of the DBM substrate 108a can be or can include a patterned metal layer including one or more electrically conductive traces. In some implementations, the first metal layer 109b and/or the second metal layer 109c can be, or can include a patterned layer configured to form one or more electrical circuits, one or more patterned metal layers or metal layer portions, one or more conductive blind and/or through vias, and/or so forth.

In some implementations, the DBM substrate 108a can be, or can include a direct bonded copper (DBC) substrate (e.g., a DBM with copper metal layers). In some implementations, such as in DBC substrate implementations, the first metal layer 109b and/or the second metal layer 109c is a copper layer. In some implementations, an AMB substrate can be included in the semiconductor device package 100a in place of the DBM substrate 108a. An AMB substrate can include an insulating layer (e.g., the insulating layer 109a) and one or metal layers (e.g., the first metal layer 109b and the second metal layer 109c) that are coupled with the insulating layer using one or more metal brazing processes (operations).

As shown in FIG. 1A, the semiconductor device package 100a further includes a semiconductor die 110 that has a top side metallization layer 110a and a bottom side metallization layer 110b (back side metal layer). In this example, the top side metallization layer 110a is a patterned metallization layer, while the bottom side metallization layer 110b is a blanket metal layer (e.g., is not patterned). The semiconductor die 110 (e.g., the bottom side metallization layer 110b) is coupled with the second metal layer 109c via a conductive bonding material 115. In some implementations, the conductive bonding material 115 can include a solder, a sintering material, or other conductive bonding material. For instance, in example implementations, the bottom side metallization layer 110b of the semiconductor die 110 can be coupled with the second metal layer 109c of the DBM substrate 108a (heat spreader) in the recess 109d using a number of different processes, such as soldering processes, sintering processes, or conductive epoxy adhesive processes.

In some implementations, soldering can be, or can include a process of joining two surfaces (e.g., metal surfaces and semiconductor surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material, a paste material, a film material, etc.) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal or metal-to-semiconductor type bonding materials.

In some implementations, coupling of components can be performed using, for example, a solder process, a sintering process (e.g., a silver sintering process, a copper sintering process), and/or other metal-to-metal or metal-to-semiconductor bonding processes.

As shown in FIG. 1A, a cavity 107 is defined in the non-conductive material 106 of the substrate 105. In this example, the cavity 107 also includes a recess 109d in the second metal layer 109c of the DBM substrate 108a. That is, the cavity 107 of the semiconductor device package 100a has a depth D1, where the recess 109d has depth D2 that is included in (is part of) the depth D1. In this example, the depth D1 corresponds with an aggregate thickness of the semiconductor die 110 and the conductive bonding material 115. That is, the semiconductor die 110 and the conductive bonding material 115 can have an aggregate thickness that is equal to the depth D1, or approximately equal to the depth D1, e.g., within processing tolerances of one or more operations used to form the cavity 107, e.g., to account for thickness tolerance variations in the DBM substrate 108a and, as result, prevent or reduce the risk of over or under drilling of via openings, the risk of tilt, and/or the risk of cracking or fracturing of the semiconductor die 110.

In the semiconductor device package 100a, the lamination material 130 is disposed between a sidewall 107a of the cavity 107 and a sidewall 110c, where the sidewall 110c is defined by the semiconductor die 110 and the conductive bonding material 115, e.g., as shown in FIG. 1A. In the semiconductor device package 100a, the lamination material 130 is further disposed on a surface of the non-conductive material 106 that surrounds, at least partially, the cavity 107, e.g., an upper surface of the non-conductive material 106 in the view of FIG. 1A.

The semiconductor device package 100a further includes a metallization layer 125 (e.g., a thick metallization layer) that is disposed on the top side metallization layer 110a of the semiconductor die 110. In this example, the metallization layer 125 includes a first portion 125a and a second portion 125b. In some implementations, the metallization layer 125 can be a copper layer that is formed using a plating operation, such as electroless plating operation or a galvanic plating operation. Depending on the particular implementation, the metallization layer 125 can be formed prior to coupling the semiconductor die 110 with the DBM substrate 108a in the cavity 107 (e.g., with the second metal layer 109c in the recess 109d, or can be formed after coupling the semiconductor die 110 with the second metal layer 109c of the DBM substrate 108a in the cavity 107.

In some implementations, the semiconductor die 110 can include a power transistor, such as a power field-effect transistor (FET). In this example, the first portion 125a of the metallization layer 125 can be disposed on a contact pad of the semiconductor die 110 that is electrically coupled with a source terminal and included in the top side metallization layer 110a. Further in this example, the second portion 125b of the metallization layer 125 can be disposed on a contact pad of the semiconductor die 110 that is electrically coupled with a gate terminal of the FET and also included in the top side metallization layer 110a. In this example, a drain terminal of the FET can be electrically coupled with the second metal layer 109c of the DBM substrate 108a via the conductive bonding material 115 and the bottom side metal layer 110b.

As shown in FIG. 1A, the semiconductor device package 100a further includes a lamination material 130 that encapsulates the semiconductor die 110 in the cavity 107, and encapsulates the metallization layer 125. In some implementations, the lamination material 130 can be a prepreg material (e.g., a fiber material that is impregnated with a resin and curing agent). In some implementations, the lamination material 130 can be formed from a plurality of layers, e.g., multiple prepreg material layers. A vacuum lamination process can be performed to facilitate encapsulation of the semiconductor die 110 and the metallization layer 125 in the lamination material 130, such as shown in FIG. 1A. In some implementations, the lamination material 130 can have a higher viscosity than the non-conductive material 106, e.g. to allow for encapsulation without altering the non-conductive material 106 (e.g., without causing a phase change in the non-conductive material 106). In some implementations, the lamination material 130 can be an epoxy-based material, a polyimide based material, or other material.

The lamination material 130 of the semiconductor device package 100a has a plurality of openings defined therein. For instance, an opening 135a is defined in the lamination material 130 and, as shown in FIG. 1A, the opening 135a extends from an upper surface of the lamination material 130, in the view of FIG. 1A, to a surface of the second metal layer 109c of the DBM substrate 108a. Openings 135b are also defined in the lamination material 130, and respectively extend from the upper surface of the lamination material 130 to a surface of the first portion 125a of the metallization layer 125. Similarly, an opening 135c is defined in the lamination material 130, and extends from the upper surface of the lamination material 130 to a surface of the second portion 125b of the metallization layer 125. The openings 135a, 135b and 135c are shown by way of example.

In some implementations additional or fewer openings can be defined in the lamination material 130. For instance, a plurality of openings 135a can be defined in the lamination material 130, e.g., a row of openings that are disposed in a line with the opening 135a shown in FIG. 1A, e.g., into the page. In some implementations, the semiconductor device package 100a can include fewer or more of the openings 135b. For instance, an array of the openings 135b can be defined in the lamination material 130. In some implementations, the semiconductor device package 100a could also include additional openings 135c in the lamination material 130, e.g., a row of openings that are disposed in line with the opening 135c shown in FIG. 1A, e.g., into the page.

As shown in FIG. 1A, respective conductive vias are disposed in the openings 135a, 135b and 135c. For instance, a conductive via 140a is disposed in the opening 135a, conductive vias 140b are disposed in the openings 135b, and a conductive via 140c is disposed in the opening 135c. In some implementations, additional conductive vias (or fewer conductive vias) can be included, e.g., one conductive via in each of the openings 135a, 135b and 135c that are defined in the lamination material 130.

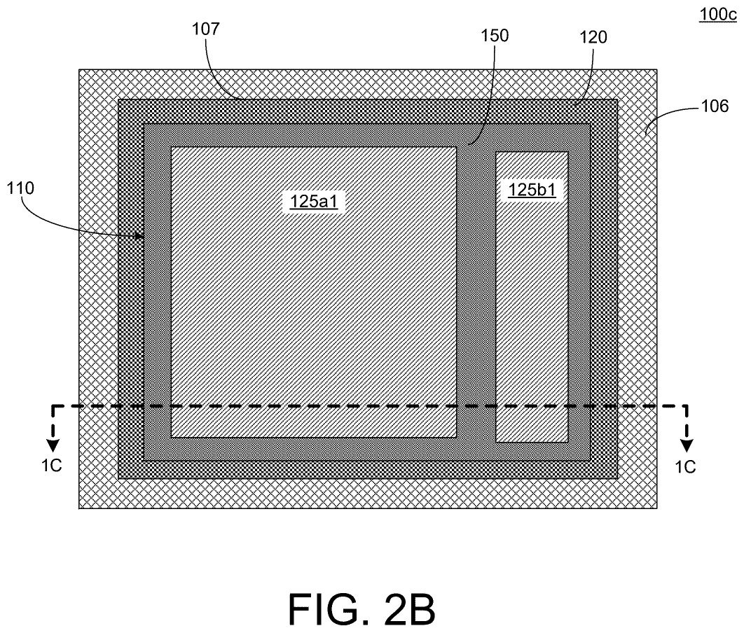

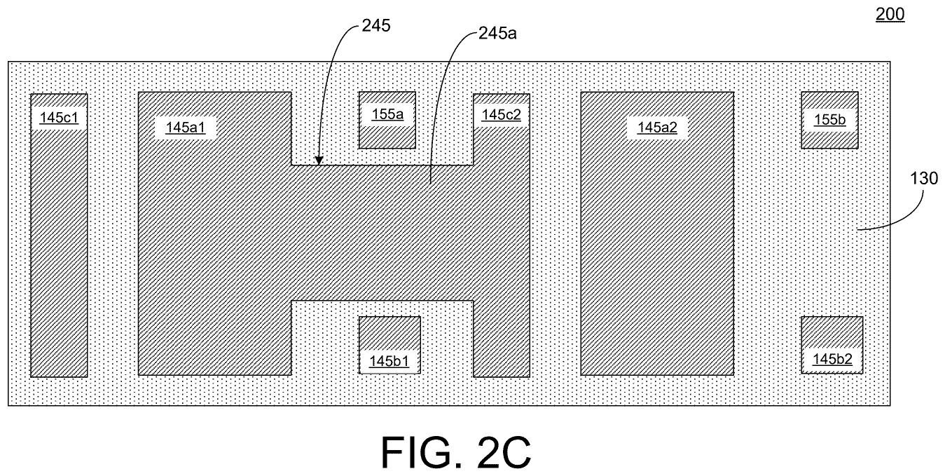

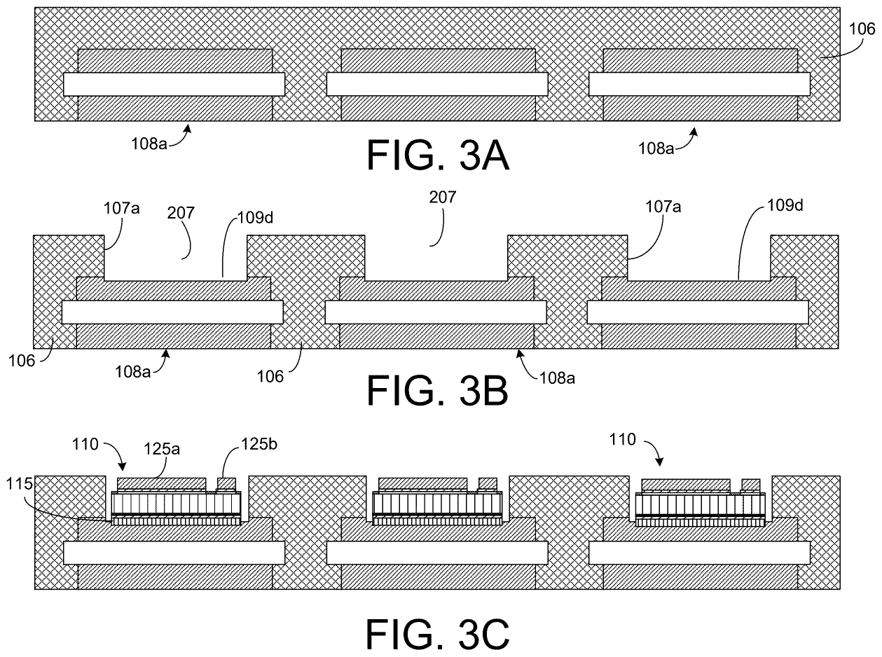

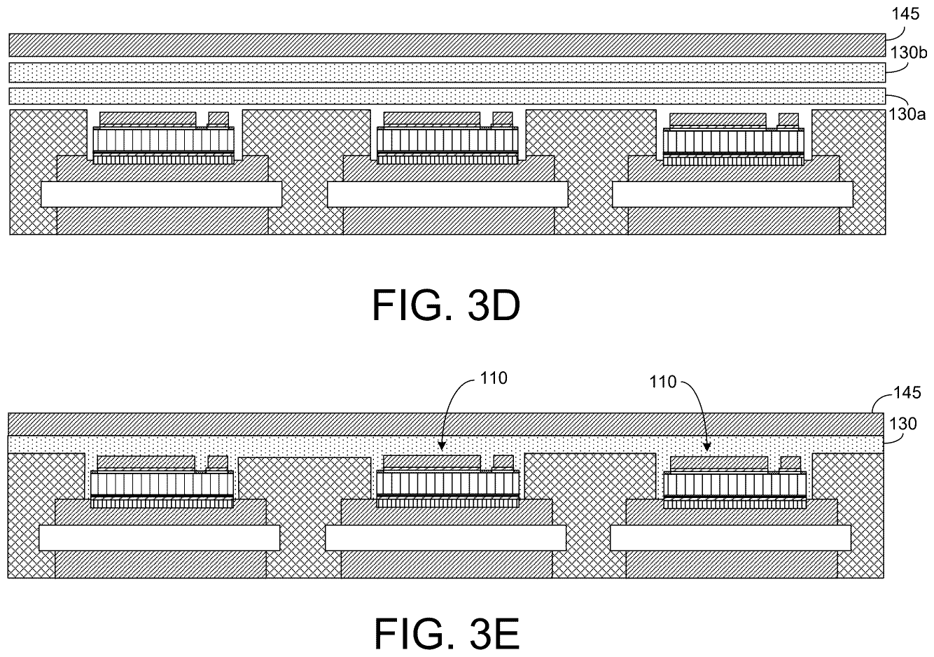

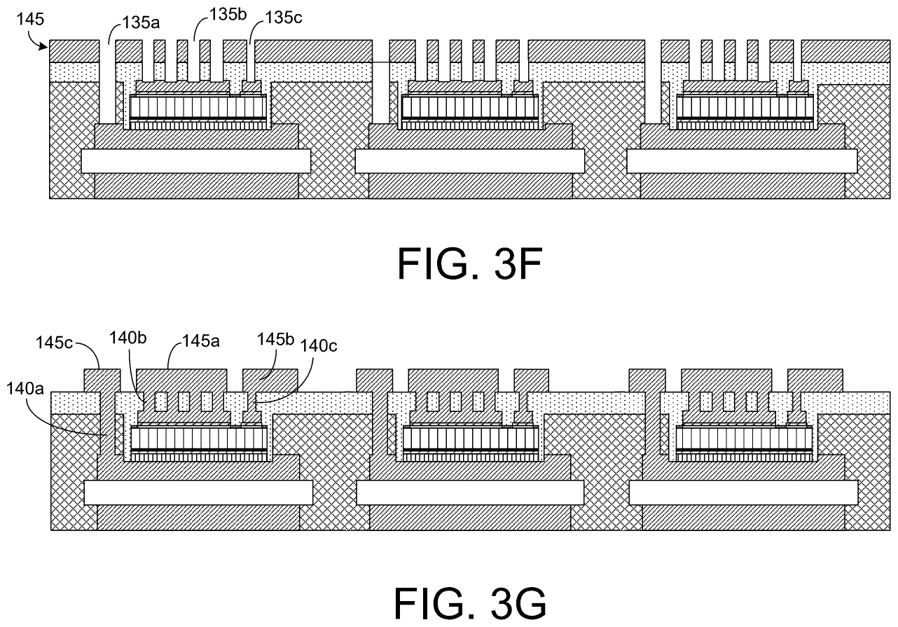

As further shown in FIG. 1A, the semiconductor device package 100a can include a metal layer 145 that is patterned to define a first portion 145a, a second portion 145b and a third portion 145c. In some implementations, the metal layer 145 can be patterned to include additional portions, such as in the examples described below with respect to, at least, FIGS. 2A and 2C. The metal layer 145 can be formed using one or more processes, such as those illustrated and described below with respect to, at least, FIGS. 3D to 3G. In the semiconductor device package 100a, the first portion 145a of the metal layer 145 is electrically coupled with the first portion 125a of the metallization layer 125 by the conductive vias 140b. The second portion 145b of the metal layer 145 is electrically coupled with the second portion 125b of the metallization layer 125 by the conductive via 140c. The third portion 145c of the metal layer 145 is electrically coupled with the second metal layer 109c of the DBM substrate 108a by the conductive via 140a.

The semiconductor die 110 of the semiconductor device package 100a can be referred to as being an embedded semiconductor die, that is, the semiconductor die 110 is embedded in the lamination material 130, e.g., by at least one lamination material layer on the substrate 105 (e.g., covering the opening of the cavity 107 and the semiconductor die 110) and performing a lamination process (e.g., vacuum lamination process) to embed (e.g., encapsulate) the semiconductor die 110 in the lamination material 130, e.g., as shown FIG. 1A.

FIG. 1B is a diagram schematically illustrating a cross-sectional view of another example semiconductor device package 100b. The semiconductor device package 100b is similar to the semiconductor device package 100a. Accordingly, for purposes of brevity, details of the semiconductor device package 100b corresponding with like details of the semiconductor device package 100a are not described again in detail with respect to FIG. 1B. The semiconductor device package 100b differs from the semiconductor device package 100a in that a metal coin 108b (metal plate, metal die attach paddle, etc.) is used as a heat spreader in place of the DBM substrate 108a in FIG. 1A. A recess 109d1 (corresponding with recess 109d of the semiconductor device package 100a) is formed in the metal coin 108b, and the semiconductor die 110 is coupled with the metal layer 109c1 of the DBM substrate 108a in the recess 109d1. As with the semiconductor device package 100a, a depth of the cavity 107 of the semiconductor device package 100c can be referenced from the upper surface of the non-conductive material 106 so that the depth corresponds with an aggregate thickness of the semiconductor die 110 and conductive bonding material 115.

FIG. 1C is a diagram schematically illustrating a cross-sectional view of another example semiconductor device package 100c. The semiconductor device package 100c, as with the semiconductor device package 100a, includes a panel (substrate) including non-conductive material 106 and a DBM substrate 108c, which could also be an AMB substrate in some implementations. The non-conductive material 106 and a metal layer 109c1 of the DBM substrate 108c have a cavity 107 defined therein, where the cavity 107 includes a recess 109d2 formed in the metal layer 109c1. A semiconductor die 110 is disposed in the cavity 107 and coupled with the second metal layer 109c1 in the recess 109d 2 with conductive bonding material 115.

As with the cavity 107 of the semiconductor device package 100a, the cavity 107 of the semiconductor device package 100c can be formed having a depth that is referenced to a surface of the non-conductive material 106 (e.g., an upper surface of the non-conductive material 106 in the view of FIG. 1C), such that the depth of the cavity 107 corresponds with an aggregate thickness of the semiconductor die 110 and the conductive bonding material 115, e.g., is coplanar with, or approximately coplanar with an upper surface of the top side metallization layer 110a of the semiconductor die 110. Such an approach can account for thickness tolerance variations in the DBM substrate 108c and, as result, prevent or reduce the risk of over or under drilling of via openings, the risk of tilt, and/or the risk of cracking or fracturing of the semiconductor die 110.

In the semiconductor device package 100c, an underfill material 120 is disposed between a sidewall 107c of the cavity 107 and a sidewall 110c that is defined by the top side metallization layer 110a and the conductive bonding material 115. The underfill material 120 can be an epoxy material that embeds the semiconductor die 110 in the cavity 107. As shown in FIG. 1C, the semiconductor die 110 includes a protective layer 150 (which can also be included in the semiconductor die of the semiconductor device package 100a and the semiconductor device package 100b. In some implementations, the protective layer 150 can be a passivation layer, a polyimide layer, or other material to protect the semiconductor die 110 from damage during processing operations for producing the semiconductor device package 100c.

The semiconductor die 110 of the semiconductor device package 100c also includes a metallization layer 125c including a first portion 125a1 and a second portion 125b1, which can be formed using a plating operation (e.g., an electroless copper plating operation) after coupling the semiconductor die 110 with the second metal layer 109c1 in the cavity 107. As compared with the semiconductor device package 100a and the semiconductor device package 100b, the semiconductor device package 100c excludes a lamination material. However, in some implementations, a lamination material could be included in the semiconductor device package 100c to further embed the semiconductor die 110, the underfill material 120, and the metallization layer 125c in the cavity 107.

FIG. 2A is a diagram schematically illustrating a top side view of the semiconductor device package 100a of FIG. 1A, though FIG. 2A could also be a top side view of an implementation of the semiconductor device package 100b of FIG. 1B. In FIG. 2A, a section line 1A-1A corresponding with the cross-sectional view of FIG. 1A (and the cross-sectional view of FIG. 1B) is shown.

As shown in FIG. 2A, the first portion 145a, the second portion 145b, and the third portion 145c of the metal layer 145 are disposed on the lamination material 130 of the semiconductor device package 100a (and respective underlying conductive vias). That is the first portion 145a, second portion 145b the third portion 145c of the metal layer 145 can be formed as contiguous metallization with their respective conductive vias 140b, 140c and 140a to provide electrical connections with a semiconductor die included in the semiconductor device package 100a, such as described with respect to FIG. 1A. As noted above, the semiconductor device package 100a can include additional conductive vias than those shown in FIG. 1A. For instance, a plurality of conductive vias 140a could be arranged in a line beneath the third portion 145c of the metal layer 145 and/or an array of conductive vias 140b could be included beneath the first portion 145a of the metal layer 145.

FIG. 2A also includes metallization 155, which can be a fourth portion of the metal layer 145, or could be formed separately from the metal layer 145. In this example, the semiconductor device package 100a can include a semiconductor die including a power transistor, such as a FET transistor, and the metallization 155 can provide an electrical connection (using respective conductive vias) to a thermal sense device, such as a positive-temperature-coefficient (PTC) device, or can provide an electrical connection for source voltage/current sensing for the FET transistor. In some implementations, additional metallization can also be included to facilitate other electrical connections for the semiconductor device package 100a.

FIG. 2B is a diagram schematically illustrating a top side view of the semiconductor device package 100c of FIG. 1C. In FIG. 2B, a section line 1C-1C corresponding with the cross-sectional view of FIG. 1C is shown.

As shown in FIG. 2B, the underfill material 120 is disposed around the semiconductor die 110, e.g., the underfill material 120 surrounds a perimeter of the semiconductor die 110. An example arrangement of the first portion 125a1 and the second portion 125b1 of the metallization layer 125c, and the protective layer 150 of the semiconductor die 110 are also shown in FIG. 2B. In this view, the non-conductive material 106 (e.g., an upper surface of the non-conductive material 106) is shown as being disposed around a perimeter of the cavity 107 in which the semiconductor die 110 and the underfill material 120 are disposed (embedded). That is, in this example, the surface of the non-conductive material 106 shown in FIG. 2B surrounds the perimeter of the cavity 107.

FIG. 2C, is a diagram schematically illustrating another example semiconductor device package 200 that can be produced using the approaches described herein. In this example, the semiconductor device package 200 can implement a half-bridge circuit, e.g. can include a first semiconductor die including a high-side power FET and a second semiconductor die including a low-side power FET. In this example, each of the semiconductor die of the semiconductor device package 200 can be embedded in a respective cavity with the lamination material 130, and the semiconductor device package 200 can be produced using the approaches described herein. For instance, the semiconductor device package 200 can be produced as part of a panel in which a plurality of embedded semiconductor die are included. The semiconductor device package 200, as well as other semiconductor device packages, can then be singulated (cut) from the corresponding panel. In some implementations, semiconductor device packages produced in such a panel can implement circuits of a same configuration, or can implement circuits of different configurations. Accordingly, the half-bridge circuit of FIG. 2C is given by way of example and for purposes of illustration.

In the half-bridge circuit example of FIG. 2C, a metal layer portion 145c1 can be electrically coupled with a drain terminal of the high-side power FET of the half-bridge circuit. That is, the metal layer portion 145c1 can implement a power supply (DC+) terminal of the half-bridge circuit. Further in this example, a metal layer portion 145a1 can be electrically coupled with a source terminal of the high-side power FET, a metal layer portion 145c2 can be electrically coupled with a drain terminal of the low-side power FET of the half-bridge circuit, and a metal layer portion 245a can electrically couple the metal layer portion 145a1 with the metal layer portion 145c2 to define metallization 245. That is, the metallization 245 can implement an output (AC) terminal of the half bridge circuit. Also in the example of FIG. 2C, a metal layer portion 145a2 can be electrically coupled with a source terminal of the low-side power FET. That is, the metal layer portion 145a2 can implement a ground (DC−) terminal of the half-bridge circuit.

Still further in the example of FIG. 2C, a metal layer portion 145b1 can be electrically coupled with a gate terminal of the high-side power FET, a metal layer portion 145b2 can be electrically coupled with a gate terminal of the low-side power FET, a metal layer portion 155a can be coupled to a thermal sensing device of the high-side power FET, and a metal layer portion 155b can be electrically coupled with a thermal sensing device of the low-side power FET. In some implementations, the semiconductor device package 200 can implement a different circuit, and the metal layer portions and metallization of the semiconductor device package 200 can implement respective terminals of that circuit.

FIGS. 3A to 3G are diagrams schematically illustrating a manufacturing process for producing a semiconductor device package, such as the semiconductor device package 100a of FIG. 1A. For purposes of illustration, FIGS. 3A to 3G are cross-sectional views corresponding with the section line 1A-1A in FIG. 2A. Accordingly, by way of example and for purposes of illustration, the process of FIGS. 3A to 3G is described with further reference to FIGS. 1A, 1B and 2A, using like 100-series reference numbers. For purposes of clarity, some structure is not shown in FIGS. 3A to 3G, such as structure that is behind structure disposed along the section line 1A-1A in FIG. 2A, where that structure, if illustrated, would obscure the illustrated views. For instance, portions of the lamination material layers in FIG. 3F are not shown.

As shown in FIG. 3A, a panel is produced, where the panel includes a plurality of heat spreaders (DBM substrates 108a) that are included in non-conductive material 106. The DBM substrates 108a can be referred to as being embedded in (surrounded by, set in, etc.) the non-conductive material 106. In some implementations, such as implementations used to produce the semiconductor device package 100b of FIG. 1B, the heat spreaders can be implemented using metal coins, metal plates, conductive die attach paddles, etc., such as shown in FIG. 1B.

As discussed with respect to FIG. 1A (equally applying to FIGS. 1B and 1C), the non-conductive material 106 can, as some examples, be an elastomeric material, an organic material, a phenolic material, or a PCB/FR-4 material. While three DBM substrates 108a (and their corresponding structures) are shown in FIGS. 3A to 3G, in some implementation, a panel can include additional heat spreaders, that can be used for producing corresponding semiconductor device packages.

As shown in FIG. 3B, cavities 207 are formed in the non-conductive material 106, where the cavities 207 include corresponding recesses 109d in respective metal layers of the DBM substrates 108a). In some implementations, the cavities 207 can be formed using mechanical milling, where the cavities 207 have a same depth that is referenced from the upper surface of the non-conductive material 106. That is, if respective thicknesses of the DBM substrate 108a vary, the depth of the respective recesses 109d will also vary to maintain consistent depths for each of the cavities 207.

As shown in FIG. 3C, semiconductor die 110 can be respectively coupled with the DBM substrates 108a in the cavities 207 using conductive bonding material 115, e.g., solder, sinter material, or other conductive bonding material. In some implementations, the metallization layers 125 (e.g., first portions 125a and second portions 125b) can be formed prior to coupling the semiconductor die 110 with their respective DBM substrates 108a, or can be formed after coupling the semiconductor die 110 with their respective DBM substrates 108a. In some implementations, each of the semiconductor die 110 can implement a same device, e.g., FETs or other devices.

In some implementations, the semiconductor die 110 can implement different devices, e.g., FETs and fast-recovery diodes (FRDs), or other combinations. In some implementations, such as the example of FIG. 2C, a semiconductor device package can include two or more DBM substrates 108a, along with corresponding non-conductive material 106, respective semiconductor die 110, lamination material (e.g., lamination material 130) and electrical interconnections, such as conductive vias and metallization layers.

For instance, in some implementations, one or more semiconductor die (e.g., one or more semiconductor components) of a semiconductor device package can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a half-bridge circuit, a full-bridge circuit, a fast recovery diode (FRD), a diode, and/or so forth. In some implementations, one or more semiconductor die can be (e.g., can be a portion of), or can include a component for an electrical vehicle (EV).

In some implementations, different semiconductor die of a semiconductor device package (when more than one semiconductor die is included) can be fabricated using different semiconductor substrates (e.g., a silicon carbide (SiC) substrate, a silicon (Si) substrate, a gallium nitride (GaN) substrate, etc.). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT or MOSFET can be fabricated using a SiC substrate, while a controller can be fabricated using a silicon substrate.

In example implementations, a first semiconductor die can be connected to a second semiconductor die, for example, by an electrical connection (e.g., a wire bond, an electrical clip, metal traces, etc.) extending from the first die to the second die, such as portions of metallization (e.g., the metallization 245 of FIG. 2C) extending between conductive vias that are respectively electrically coupled with the first semiconductor die and the second semiconductor die.

FIG. 3D illustrates layering of lamination material layers for embedding the semiconductor die 110 in their respective cavities 207. As shown in FIG. 3C, a lamination material layer 130a is disposed on the panel and covers the cavities 207 and the semiconductor die 110 respectively disposed in the cavities 207. As also shown in FIG. 3D, a lamination material layer 130b is disposed on the lamination material layer 130a. In some implementations, a single lamination material layer, or additional lamination material layers can be used. In this example, a metal layer 145, e.g., a copper metal layer, is disposed on the lamination material layer 130b, where the metal layer 145 can define, at least in part, the metal layer portions 145a, 145b and 145c of the semiconductor device package 100a in FIG. 1A (or like structure of the semiconductor device package 100b of FIG. 1B).

As shown in FIG. 3E, a lamination process (e.g., a vacuum lamination process) is performed to produce the lamination material 130 from the lamination material layers 130a and 130b (e.g., prepreg material layers). For instance, with the structure shown in FIG. 3D being disposed in a vacuum chamber, mechanical pressure can be applied to the metal layer 145 and, as a result, the lamination material layers 130a and 130b. Heat can then be applied to cause material of the lamination material layers 130a and 130b to flow and embed the respective semiconductor die 110 and their respective metallization layers 125 in the lamination material 130. That is, the vacuum lamination process of FIG. 3E can result in material from the lamination material layer 130a and/or the lamination material layer 130b to flow into the spaces between respective sidewalls 107a of the cavities 207 and respective sidewalls 110c defined by the semiconductor die 110 and their corresponding conductive bonding material 115, such as shown by the lamination material 130 in the FIG. 3E.

FIG. 3F illustrates formation of the openings 135a, 135b and 135c in the lamination material 130 (and the metal layer 145 in this example). In some implementations, the openings 135a to 135c can be formed using laser ablation, mechanical milling, etching, etc. In some implementations, the openings 135a to 135c can be micro-via openings.

After forming the openings 135a to 135c, as shown in FIG. 3G, a plating operation (e.g., a galvanic copper plating operation) can be performed to form the conductive vias 140a, 140b and 140c, as well as form additional metallization on the upper surface of the lamination material 130. Photolithography and etch operations can then be performed to define (structure, pattern, etc.) the metal layer portions 145a, 145b and 145c (and/or other metal layer portions as appropriate for a particular implementation).

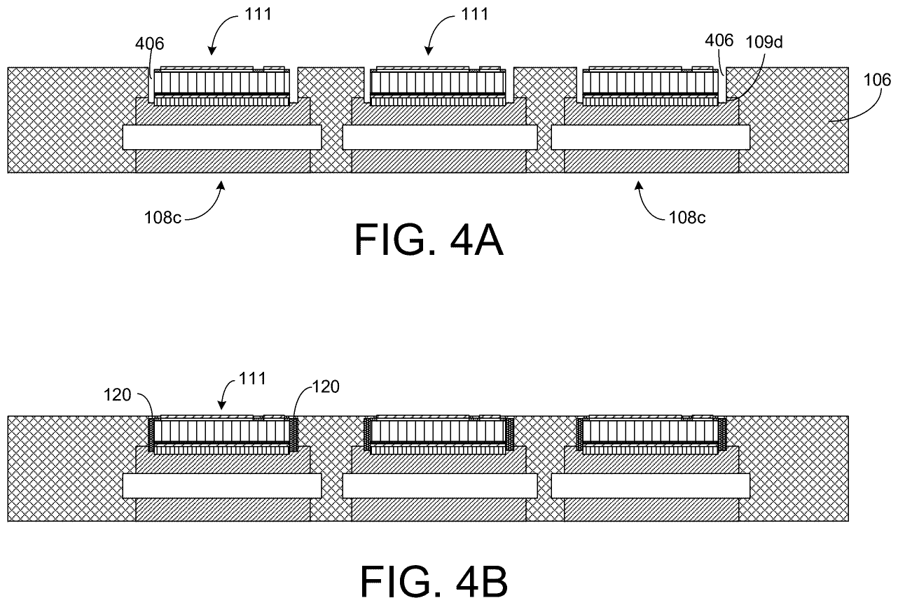

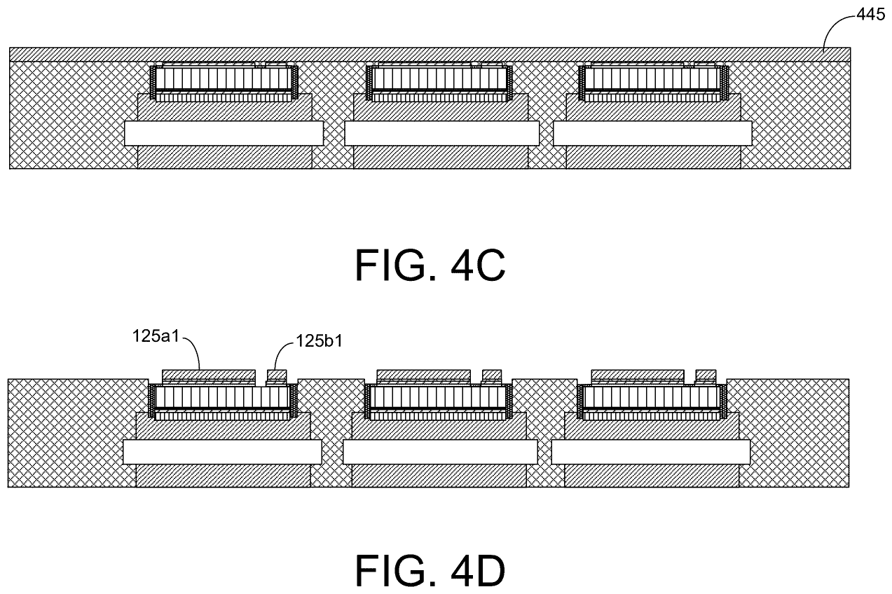

FIGS. 4A to 4D are diagrams schematically illustrating a manufacturing process for producing a semiconductor device package, such as the semiconductor device package 100c of FIG. 1C. In some implementations, the process of FIGS. 4A to 4D can be performed in conjunction with similar operations as shown in FIGS. 3A and 3B, e.g., forming a panel, and forming cavities in the panel. For purposes of illustration, FIGS. 4A to 4D are cross-sectional views corresponding with the section line 1C-1C in FIG. 2B. Accordingly, by way of example and for purposes of illustration, the process of FIGS. 4A to 4D is described with further reference to FIGS. 1C and 2B, using like 100-series reference numbers.

As shown in FIG. 4A, respective semiconductor die 111 be coupled with DBM substrates 108c of the panel, e.g., in respective recesses 109d. As shown in FIG. 4A, the cavities in the panel can be larger than the semiconductor die 111, such that there are respective spaces 406 between the non-conductive material 106 of the panel and the semiconductor die 111 disposed (embedded) in the respective cavities.

As shown in FIG. 4B, underfill material 120 is formed in the spaces 406. In some implementations, the underfill material 120 can at least partially surround respective respective perimeters of the semiconductor die 110, or can completely surround their perimeters. In some implementations, forming the underfill material 120 can include depositing (dispensing, injecting, etc.) a low-viscosity epoxy material into the respective spaces 406 followed by a cure operation, such as a bake operation.

FIG. 4C illustrates formation of a metal layer 445 on the upper surface of the structure of FIG. 4B, In some implementations, the metal layer 445 can be formed using a galvanic copper plating operation. In some implementations, a thin layer of metallization (e.g., a seed layer) can be disposed on the upper surface of the structure shown in FIG. 4B, e.g., to facilitate the plating operation of FIG. 4D.

As shown in FIG. 4D, photolithography and etch operations are then be performed to define (structure, pattern, etc.) the respective portions 125a and 125b of the metallization layers 125 of the semiconductor die 110 from the metal layer 445. In some implementations, the metallization layer 125 (e.g., of the semiconductor device package 100a, the semiconductor device package 100b and/or the semiconductor device package 100c) can have a thickness of 10 micrometers (μm) or greater. For instance, in some implementations, the metallization layer 125 can have a thickness of 25 μm, 50 μm, 100 μm, etc. In some implementations, due to the planarity of the metal layer 445, a dry film photo resist can be used for structuring the metal layer 445 as shown in FIG. 4D.

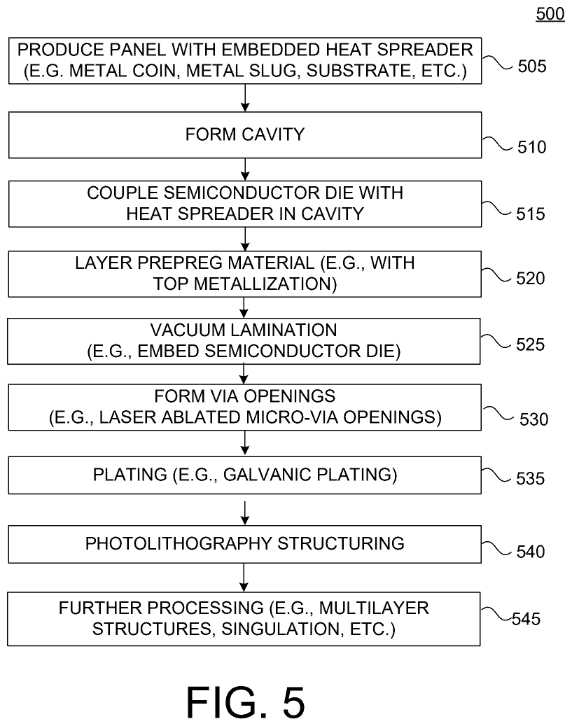

FIG. 5 is a flowchart illustrating a method 500 for producing a semiconductor device assembly. In some implementations, the method 500 can be implemented using the process of FIGS. 3A to 3G to produce the semiconductor device package 100a of FIG. 1A and/or the semiconductor device package 100b of FIG. 1B. Accordingly, for purpose of illustration, the method 500 is described with further reference to FIGS. 1A, 1B and 3A to 3G.

At operation 505, the method 500 includes producing a panel with embedded heat spreaders, such as the panel of FIG. 1A to 1C or 3A. For instance, in some implementations, the heat spreaders can be metal plates, metal coins, metal slugs DBM substrates, AMB substrates, etc. that are embedded in a non-conductive material 106, such as a PCB material. At operation 510, the method 500 includes forming cavities in the panel, such as the cavities shown in FIG. 1A to 1C, or 3B (e.g., including respective recesses in the corresponding heat spreaders, such as the recesses 109d in respective metal layers of the DBM substrates 108a).

At operation 515, the method 500 includes coupling respective semiconductor die with the heat spreaders in respective cavities using a conductive bonding material (conductive bonding material 115). The operation 515 can include coupling the semiconductor die with the heat spreaders using soldering, sintering, or other attachment processes.

At operation 520, lamination material layers (and a metal layer) can be disposed on the panel, such as the arrangement of the lamination material layers 130a and 130b, and the metal layer 145 in FIG. 3D. At operation 525, a vacuum lamination operation can be performed to embed the semiconductor die in a lamination material, such as the lamination material 130 illustrated in FIG. 3E (e.g., produced from the lamination material layers 130a and 130b). At operation 530, openings (via openings) are formed, such as the openings 135a, 135b and 135c of the semiconductor device package 100a (e.g., as shown FIG. 3F).

At operation 535, a plating operation can be performed (e.g. a galvanic copper plating operation) to form conductive vias, such as the conductive vias 140a to 140c, as well as to form metallization (e.g., additional metallization) on an upper surface of the lamination material of operation 525. At operation 540, photolithography structuring of the metallization on the surface of the lamination material can be performed, e.g., to define the respective metal layer portions 145a to 145c of a plurality of the semiconductor device packages 100a. At operation 545, additional processing can be performed. Such additional processing can include separating the panel into individual semiconductor device packages including one or more semiconductor die (along with corresponding heat spreaders and other structure, such as respective cavities, formed by the operations 505 to 540).

In some implementations, such further processing can include forming additional structures, which can include other semiconductor die. Such additional structures can, e.g., be formed on top of the structures formed by the operations 505 to 540. That is, semiconductor device packages (or modules) formed using the method 500 (and/or the process of FIGS. 3A to 3G) can be included in another package or module. For example, one or more modules or packages can be one or more sub modules or packages included within another module or package. In other words, a first module or package can be included as a sub module or package within a second module or package.

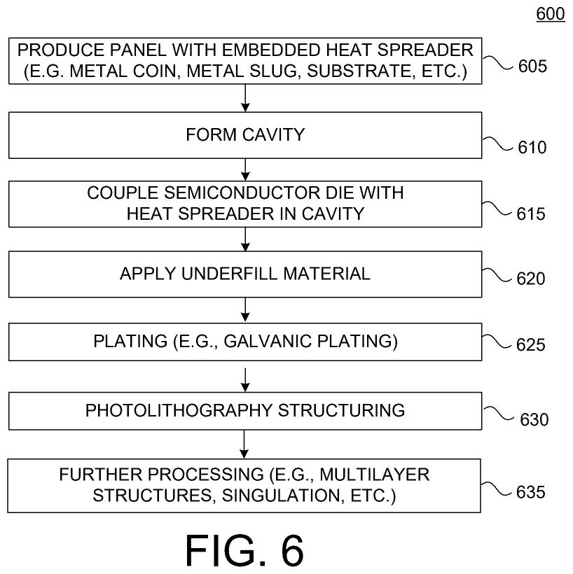

FIG. 6 is a flowchart illustrating a method 600 for producing a semiconductor device assembly. In some implementations, the method 600 can be implemented using the process of FIGS. 4A to 4D (in conjunction with operations similar to the operation of FIGS. 3A and 3B) to produce the semiconductor device package 100b of FIGS. 1C and 2B. Accordingly, for purpose of illustration, the method 600 is described with further reference to FIGS. 1C, 2B, 3A and 3B.

At operation 605, the method 600 includes producing a panel with embedded heat spreaders, such as the panels of FIG. 1A to 1C or FIG. 3A. For instance, in some implementations, the heat spreaders can be metal plates, metal coins, metal slugs DBM substrates, AMB substrates, etc. that are embedded in a non-conductive material 106, such as a PCB material. At operation 610, the method 600 includes forming cavities in the panel, such as the cavities shown in FIG. 3B (e.g., including respective recesses in the corresponding heat spreaders, such as the recesses 109d in a metal layer of the DBM substrate 108a).

At operation 615, the method 600 includes coupling respective semiconductor die with the heat spreaders in respective cavities using conductive bonding material (conductive bonding material 115), such as shown in FIG. 4A. The operation 615 can include coupling the semiconductor die with the heat spreaders using soldering, sintering, or other attachment processes. At operation 620, an underfill material (e.g., the underfill material 120) is formed in spaces (e.g., spaces 406) between respective sidewalls of the semiconductor die and respective sidewalls of the cavities, which embeds the semiconductor die in the cavities.

At operation 625, a plating operation can be performed (e.g. a galvanic copper plating operation) to form a metal layer, such as the metal layer 445 in FIG. 4C. At operation 630, the method 600 includes performing photolithography structuring of the metal layer 445, e.g., to form respective metallization layers 125 (e.g., portions 125a and 125b) for the semiconductor die embedded in the cavities. At operation 635, additional processing can be performed. Such additional processing can include lamination embedding, and/or separating the panel into individual semiconductor device packages including one or more semiconductor die (along with corresponding heat spreaders and other structure, such as respective cavities, formed by the operations 605 to 630).

In some implementations, such further processing can include forming additional structures, which can include other semiconductor die. Such additional structures can, e.g., be formed on top of the structures formed by the operations 605 to 630. That is, semiconductor device packages (or modules) formed using the method 600 (and/or the process of FIGS. 4A to 4D, as describe above) can be included in another package or module. For example, one or more modules or packages can be one or more sub modules or packages included within another module or package. In other words, a first module or package can be included as a sub module or package within a second module or package.

In a general aspect, a method for producing a semiconductor device package includes forming a panel including a heat spreader that is disposed in a non-conductive material. A first surface of the heat spreader is exposed through a first side of the non-conductive material and a second surface of the heat spreader opposite the first surface is embedded in the non-conductive material. The method further includes forming, on a second side of the non-conductive material opposite the first side, a cavity in the non-conductive material to expose the second surface of the heat spreader. Forming the cavity includes forming a recess in the second surface of the heat spreader. The method also includes coupling a semiconductor die to the second surface of the heat spreader with a conductive bonding material. The semiconductor die is disposed in the cavity. The method further includes embedding the semiconductor die in a lamination material, disposing a metal layer on the lamination material, and forming an opening in the metal layer and the lamination material to expose at least a portion of a contact pad of the semiconductor die, The method also includes forming a conductive via in the opening in the metal layer and the lamination material. The conductive via electrically couples the metal layer with the contact pad.

Implementations can include one or more of the following features, alone or in combination. For example, embedding the semiconductor die in the lamination material can include disposing a lamination material on the second side of the non-conductive material and the semiconductor die, where the lamination material covers the opening in the non-conductive material. A vacuum lamination operation can be performed to embed the semiconductor die and the contact pad in the lamination material.

The non-conductive material can include a printed circuit board material. The lamination material can include at least one layer of a prepreg material.

Forming the opening in the metal layer and the lamination material can include forming the opening using laser ablation.

The method can include patterning the metal layer.

Forming the conductive via can include forming the conductive via using galvanic copper plating.

Forming the cavity in the non-conductive material can include milling the non-conductive material and the second surface of the heat spreader such that the cavity has a depth corresponding with a thickness of the semiconductor die. The depth can be referenced from a surface of the second side of the non-conductive material.

The opening in the metal layer and the lamination material can be a first opening. The conductive via can be a first conductive via. The method can include forming a second opening in the metal layer, the lamination material and the non-conductive material to expose a portion of the heat spreader. The method can include forming a second conductive via in the second opening. The second conductive via can electrically couple the metal layer with the heat spreader.

Coupling the semiconductor die with the second surface of the heat spreader can include sintering the semiconductor die to the heat spreader in the recess.

In another general aspect, a method for producing a semiconductor device package includes forming a panel including a heat spreader that is disposed in a non-conductive material. A first surface of the heat spreader is exposed through a first side of the non-conductive material, and a second surface of the heat spreader opposite the first surface is embedded in the non-conductive material. The method further includes forming, on a second side of the non-conductive material opposite the first side, a cavity in the non-conductive material to expose the second surface of the heat spreader. Forming the cavity includes forming a recess in the second surface of the heat spreader. The method also includes coupling a semiconductor die to the heat spreader with a conductive bonding material. The semiconductor die is disposed in the cavity. The method further includes applying an underfill material between a sidewall of the cavity and a sidewall of the semiconductor die. The method also includes forming, on the second side of the non-conductive material, a metal layer disposed on the non-conductive material, the underfill material and the semiconductor die. The method also includes patterning the metal layer to define at least one terminal of the semiconductor die.

Implementations can include one or more of the following features, alone or in combination. For example, the non-conductive material can include a printed circuit board material. The underfill material can include an epoxy material.

Forming the cavity can include milling the non-conductive material and the second surface of the heat spreader such that the cavity has a depth corresponding with a thickness of the semiconductor die. The depth can be referenced from a surface of the second side of the non-conductive material.

Forming the metal layer can include forming the metal layer using galvanic copper plating.

Coupling the semiconductor die with the heat spreader can include sintering the semiconductor die to the heat spreader in the recess.

In another general aspect, a semiconductor device package includes a substrate including a non-conductive material, and a heat spreader disposed in the non-conductive material. A first surface of the heat spreader is exposed through a first side of the non-conductive material. The package further includes a semiconductor die disposed in a cavity defined in a second side of the non-conductive material opposite the first side. The semiconductor die is electrically coupled with the heat spreader in a recess defined in a second surface of the heat spreader opposite the first surface. The recess corresponds with the cavity in the non-conductive material. The package also includes a patterned metal layer. The patterned metal layer is electrically coupled with at least one of the semiconductor die or the heat spreader.

Implementations can include one or more of the following features, alone or in combination. For example, the package can include a lamination material disposed on the second side of the non-conductive material and the semiconductor die. The semiconductor die can be embedded in the lamination material.

The patterned metal layer can be electrically coupled with the semiconductor die by a conductive via defined in an opening in the lamination material.

The patterned metal layer can be electrically coupled with the heat spreader by a conductive via defined in an opening in the lamination material and the non-conductive material.

The non-conductive material can include a printed circuit board material. The lamination material can include at least one layer of a prepreg material.

The package can include an underfill material disposed between a sidewall of the cavity and a sidewall of the semiconductor die. The underfill material can include an epoxy material. The underfill material can be disposed around an entire perimeter of the semiconductor die.

The heat spreader includes one of: a metal plate; or a direct-bonded metal substrate.

The heat spreader can be a first heat spreader, the semiconductor die can be a first semiconductor die, and the cavity can be a first cavity. The package can include a second heat spreader disposed in the non-conductive material. A first surface of the second heat spreader can being exposed through the first side of the non-conductive material. The package can include a second semiconductor die disposed in a second cavity defined in the second side of the non-conductive material. The second semiconductor die can be electrically coupled with the second heat spreader in a recess defined in a second surface of the second heat spreader opposite the first surface of the second heat spreader. The recess in second heat spreader can correspond with the second cavity in the non-conductive material. The second semiconductor die can be electrically coupled with the first semiconductor die via the patterned metal layer.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method for producing a semiconductor device package, the method including:
forming a panel including a heat spreader that is disposed in a non-conductive material, a first surface of the heat spreader being exposed through a first side of the non-conductive material and a second surface of the heat spreader opposite the first surface being embedded in the non-conductive material;
forming, on a second side of the non-conductive material opposite the first side, a cavity in the non-conductive material to expose the second surface of the heat spreader, forming the cavity including forming a recess in the second surface of the heat spreader;
coupling a semiconductor die to the second surface of the heat spreader with a conductive bonding material, the semiconductor die being disposed in the cavity;
embedding the semiconductor die in a lamination material;
disposing a metal layer on the lamination material;
forming an opening in the metal layer and the lamination material to expose at least a portion of a contact pad of the semiconductor die; and
forming a conductive via in the opening in the metal layer and the lamination material, the conductive via electrically coupling the metal layer with the contact pad.

2. The method of claim 1, wherein embedding the semiconductor die in the lamination material includes:
disposing a lamination material on the second side of the non-conductive material and the semiconductor die, the lamination material covering the opening in the non-conductive material; and
performing a vacuum lamination operation to embed the semiconductor die and the contact pad in the lamination material.

3. The method of claim 2, wherein:
the non-conductive material includes a printed circuit board material; and
the lamination material includes at least one layer of a prepreg material.

4. The method of claim 1, wherein forming the opening in the metal layer and the lamination material includes forming the opening using laser ablation.

5. The method of claim 1, further comprising patterning the metal layer.

6. The method of claim 1, wherein forming the conductive via includes forming the conductive via using galvanic copper plating.

7. The method of claim 1, wherein forming the cavity in the non-conductive material includes milling the non-conductive material and the second surface of the heat spreader such that the cavity has a depth corresponding with a thickness of the semiconductor die, the depth being referenced from a surface of the second side of the non-conductive material.

8. The method of claim 1, wherein the opening in the metal layer and the lamination material is a first opening, and the conductive via is a first conductive via, the method further comprising:
forming a second opening in the metal layer, the lamination material and the non-conductive material to expose a portion of the heat spreader; and
forming a second conductive via in the second opening, the second conductive via electrically coupling the metal layer with the heat spreader.

9. The method of claim 1, wherein coupling the semiconductor die with the second surface of the heat spreader includes sintering the semiconductor die to the heat spreader in the recess.

10. A method for producing a semiconductor device package, the method including:
forming a panel including a heat spreader that is disposed in a non-conductive material, a first surface of the heat spreader being exposed through a first side of the non-conductive material and a second surface of the heat spreader opposite the first surface being embedded in the non-conductive material;
forming, on a second side of the non-conductive material opposite the first side, a cavity in the non-conductive material to expose the second surface of the heat spreader, forming the cavity including forming a recess in the second surface of the heat spreader;
coupling a semiconductor die to the heat spreader with a conductive bonding material, the semiconductor die being disposed in the cavity;
applying an underfill material between a sidewall of the cavity and a sidewall of the semiconductor die;
forming, on the second side of the non-conductive material, a metal layer disposed on the non-conductive material, the underfill material and the semiconductor die; and
patterning the metal layer to define at least one terminal of the semiconductor die.

11. The method of claim 10, wherein:
the non-conductive material includes a printed circuit board material; and
the underfill material includes an epoxy material.

12. The method of claim 10, wherein forming the cavity includes milling the non-conductive material and the second surface of the heat spreader such that the cavity has a depth corresponding with a thickness of the semiconductor die, the depth being referenced from a surface of the second side of the non-conductive material.

13. The method of claim 10, wherein forming the metal layer includes forming the metal layer using galvanic copper plating.

14. The method of claim 10, wherein coupling the semiconductor die with the heat spreader includes sintering the semiconductor die to the heat spreader in the recess.

15. A semiconductor device package comprising:
a substrate including:
a non-conductive material; and
a heat spreader disposed in the non-conductive material, a first surface of the heat spreader being exposed through a first side of the non-conductive material;
a semiconductor die disposed in a cavity defined in a second side of the non-conductive material opposite the first side, the semiconductor die being electrically coupled with the heat spreader in a recess defined in a second surface of the heat spreader opposite the first surface, the recess corresponding with the cavity in the non-conductive material; and
a patterned metal layer, the patterned metal layer being electrically coupled with at least one of the semiconductor die or the heat spreader.

16. The semiconductor device package of claim 15, further comprising:
a lamination material disposed on the second side of the non-conductive material and the semiconductor die, the semiconductor die being embedded in the lamination material.

17. The semiconductor device package of claim 16, wherein the patterned metal layer is electrically coupled with the semiconductor die by a conductive via defined in an opening in the lamination material.

18. The semiconductor device package of claim 16, wherein the patterned metal layer is electrically coupled with the heat spreader by a conductive via defined in an opening in the lamination material and the non-conductive material.

19. The semiconductor device package of claim 16, wherein:
the non-conductive material includes a printed circuit board material; and
the lamination material includes at least one layer of a prepreg material.

20. The semiconductor device package of claim 16, further comprising an underfill material disposed between a sidewall of the cavity and a sidewall of the semiconductor die.

21. The semiconductor device package of claim 20, wherein:
the non-conductive material includes a printed circuit board material; and
the underfill material includes an epoxy material.

22. The semiconductor device package of claim 20, wherein the underfill material is disposed around an entire perimeter of the semiconductor die.

23. The semiconductor device package of claim 15, wherein the heat spreader includes one of:
a metal plate; or
a direct-bonded metal substrate.

24. The semiconductor device package of claim 15, wherein the heat spreader is a first heat spreader, the semiconductor die is a first semiconductor die, and the cavity is a first cavity, the semiconductor device package further comprising:
a second heat spreader disposed in the non-conductive material, a first surface of the second heat spreader being exposed through the first side of the non-conductive material; and
a second semiconductor die disposed in a second cavity defined in the second side of the non-conductive material, the second semiconductor die being electrically coupled with the second heat spreader in a recess defined in a second surface of the second heat spreader opposite the first surface of the second heat spreader, the recess in second heat spreader corresponding with the second cavity in the non-conductive material, the second semiconductor die being electrically coupled with the first semiconductor die via the patterned metal layer.
